(19) United States
(12) Patent Application Publication
(10) Pub. No.: US 2022/0104367 A1
(43) Pub. Date: Mar. 31, 2022

(54) HINGES

(71) Applicant: HEWLETT-PACKARD DEVELOPMENT COMPANY, L.P., Spring, TX (US)

(72) Inventors: Matthew William Tivnon, 10300 Energy Drive, TX (US); Ken Maclean, Spring, TX (US); Owen P. Columbus, Spring, TX (US)

(73) Assignee: HEWLETT-PACKARD DEVELOPMENT COMPANY, L.P., Spring, TX (US)

(21) Appl. No.: 17/421,815

(22) PCT Filed: Jan. 9, 2019
(86) PCT No.: PCT/US2019/012836

§ 371 Date: Jul. 9, 2021

(51) Int. Cl. H05K 5/02

(52) U.S. Cl. CPC H05K 5/0204; H05K 5/0221; H05K 5/0226

(57) ABSTRACT

A hinge system may include a flat panel to hold a computing device thereon; a hinge coupled to the flat panel to flip the flat panel over to selectively present the computing device to one of a first and second facing users, the hinge including a clutch bearing that allows for rotation relative to a shaft in a first direction to a first of the facing users but prevents rotation of the clutch bearing relative to a shaft in a second direction; and a dampening device to allow for selective rotation of the shaft in the second direction.

### BACKGROUND

Consumers interact with point of sale representatives on a daily basis. Occasionally, at the point of sale (POS), the customer may be asked to engage in monetary transactions that involves providing financial confirmation details such as pin numbers, credit/debit card swipes, and signatures among other financial transaction activities that come with the purchase of goods and services.

### BRIEF DESCRIPTION OF THE DRAWINGS

The accompanying drawings illustrate various examples of the principles described herein and are part of the specification. The illustrated examples are given merely for illustration, and do not limit the scope of the claims.

FIG. 1 is a block diagram of a hinge system according to an example of the principles described herein.

FIG. 2 is a block diagram of a hinge for a display device according to an example of the principles described herein.

FIG. 3 is a block diagram of a support for a computing device according to an example of the principles described herein.

FIG. 4 is a perspective view of a support for a computing device according to an example of the principles described herein.

FIG. 5 is a perspective view of the arm of the hinge according to an example of the principles described herein.

FIG. 6 is a perspective interior view of the hinge shown in FIG. 4 according to an example of the principles described herein.

FIG. 7 is a side view of the hinge shown in FIG. 6 according to an example of the principles described herein.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION

At a point of sale (POS), both the customer and associate interact to exchange goods and services for monetary compensation. This interaction may include both the associate and customer using a single computing device such as a tablet device in order to provide the customer with the ability to pay for goods and services after the associate has interfaced with a cashier application being executed on the computing device. In order to facilitate this, the associate may execute the cashier application on the computing device in order to write up a bill of sale. After the associate has written the bill of sale, the customer may be asked to provide certain financial assurances or payment for the items or services represented on the bill of sale. Thus, in this example, the customer may be physically provided with the computing device in order to complete the transaction.

Passing the computing device such as the tablet device may prove difficult if the device is communicatively coupled to, for example, a cash register via a wired connection. Additionally, even if there was a wireless communication available, passing a computing device back and forth between an associated and a customer may risk damage or theft of the table device.

In order to provide for security of the computing device as well as physically protect it, the computing device may be situated on a table or other type of counter. This arrangement may provide the associate with the ability to resituate or reorient the computing device so that the customer may have access to an interface of the computing device at some point during the POS transaction. However, this too may be cumbersome because the reorientation may not be as convenient resulting from the various form factors of reorientation devices within the industry.

The present specification describes a hinge system used to allow for the computing device to be presented easily to both the associate and the customer. Although the present specification describes the use of the hinge between a customer and a POS associate, the present hinge may be used to cause any surface or device to be readily passed between two individuals. Thus, although the present hinge is described in connection with a POS situation, the present specification contemplates the use of the hinge in any given situation or for any purpose as may be described herein. Indeed, although the hinge may be used to reorient a computing device as described herein, the present hinge may be used to reorient any device or surface that may be reoriented or moved.

The present specification describes a hinge system that includes a flat panel to hold a computing device thereon; a hinge coupled to the flat panel to flip the flat panel over to selectively present the computing device to one of a first and second facing users, the hinge that includes a clutch bearing that allows for rotation about a shaft in a first direction to a first of the facing users but prevents rotation of the clutch bearing relative to a shaft in a second direction; a dampening device to allow for selective rotation of the shaft in the second direction.

The present specification also describes a hinge for a display device that includes an arm; a base mechanically coupled to the arm via a rotatable shaft; a clutch bearing to allow for free movement of the arm in a first direction about the rotatable shaft while preventing rotation of the arm about the rotatable shaft in a second direction; and a rotation dampening device to increase the resistance to rotate the arm with the rotatable shaft in the second direction.

The present specification further describes a support for a computing device that includes a shelf to hold and maintain a computing device thereon; an arm mechanically coupled to the shelf; a base portion mechanically coupled to the arm via a shaft fit into an arm hole formed in the arm and a base hole formed in the base portion; a sprag clutch bearing to allow for free movement of the arm about the shaft in a first direction while preventing movement of the arm about the shaft in a second direction; and a rotation dampening device to increase the resistance to move the arm with the shaft in the second direction.

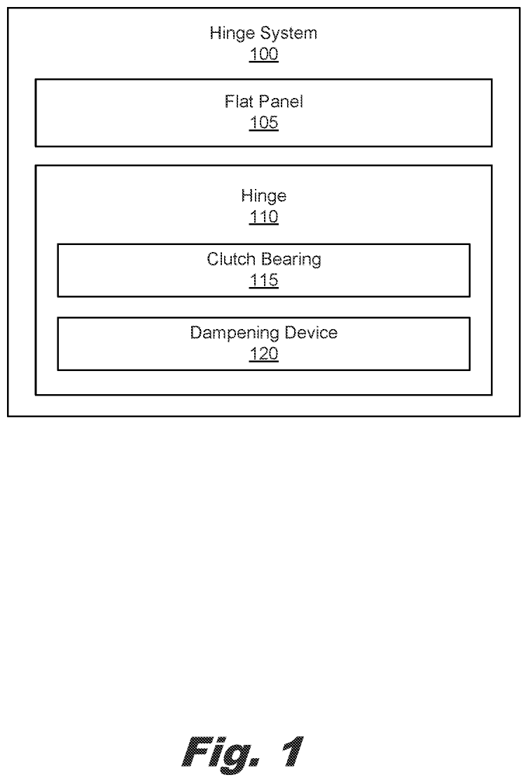

Turning now to the figures, FIG. 1 is a block diagram of a hinge system (100) according to an example of the principles described herein. The hinge system (100) may include a flat panel (105) to hold a computing device thereon. In an example, the flat panel (105) may include a latch or other fastening device to secure the computing device to the flat panel (105) in order to selectively prevent the computing device from being removed from the flat panel (105). In an example, this latch or other fastening device may have a lock associated with it in order to prevent anyone without a key, passcode, or combination from removing the computing device from the flat panel (105).

The computing device may be any type of computing device. In an example, the computing device may be a tablet-type device. In this example, the tablet device may be oriented such that a display device of the tablet-type device is presented away from the flat panel (105) so that the users may view it. In this specific example, the display of the table-type device may allow for the reorientation of the images and/or text displayed on the display. As will be understood from the orientation of the flat panel (105) and computing device described herein, the computing device may be turned upside down in order to present the computing device to a consumer or, alternative, a customer. The reorientation of images and/or text on the display allows the computing device to be flipped over without the image and/or text being upside down.

The hinge system (100) may further include a hinge (110). The hinge (110) may allow for the flat panel (105) to be flipped over so as to selectively present the computing device to one of a first and second facing users. As is described herein, the shaft may couple an arm portion of the hinge (110) to a base portion of the hinge (110). The base portion may be coupled to a counter top or other surface. The countertop may be a service counter at a POS location such that the associate stands on a first side of the counter top facing approaching customers. These associates may interface with the customer on the second side of the counter top. The arm may, via the shaft, couple the flat panel (105) to the base portion.

In order to facilitate for the rotation about the shaft, the hinge (110) may include a clutch bearing (115). The clutch bearing (115) may be coupled to the arm and mechanically coupled to the shaft such that the clutch bearing (115) allows for rotation of the arm relative to the shaft in a first direction to a first of the facing users but, as to the clutch bearing (115), prevents rotation of the clutch bearing relative to a shaft in a second direction. The clutch bearing (115) may implement any type of ratcheting mechanism and the present specification contemplates the use of any type of clutch bearing (115). In a specific example, the clutch bearing (115) is a sprag clutch bearing. The sprag clutch bearing may allow for the ratcheting of the arm of the hinge system (100) in the first direction as described. In order to allow for the clutch bearing (115), and in this specific case, the sprag clutch bearing to be coupled to the shaft, the sprag clutch bearing may include a keyway that interfaces with a spline formed on the shaft. This allows for the mechanical coupling of the clutch bearing (115) to the shaft in a rotational manner.

The hinge (110) further includes a dampening device (120). The dampening device (120) may be coupled to a housing used to house the hinge system (100) such that the dampening device (120) may be coupled mechanically to the shaft. After the clutch bearing (115) has allowed the arm to rotate about the shaft in a first direction (i.e., towards a customer opposite an associate), the dampening device (120) may allow for the rotation of the arm back in a second direction. Because the dampening device (120) is coupled to a housing of the hinge system (100), the shaft may be rotated back, albeit in a dampened manner, by controlling the rotation of the shaft relative to the dampening device (120).

In an example, the hinge system (100) may include a spring to assist in the movement of the hinge (110). In an example, the spring may assist specifically in the movement of the arm of the hinge (110) in the first direction. Because that movement of the hinge (110) is not dampened by the dampening device (120) it may cause a free fall of the arm in the first direction despite the clutch bearing (115) being present. The spring, in this example, may match the weight of the computing device, arm, and/or flat panel (105) so as to prevent a free fall of the arm as well as provide customized tilt angles relative to the customer and/or the associate. The spring, therefore, may allow for the specific adjustment of the flat panel (105) relative to the customer of any height and stature. Indeed, in an example, the flat panel (105) of the hinge system (100) may be moved in the second direction a total of 60 degrees. In an example, an infinite number of tilt angles may be achieved within this 60-degree range.

In an example, the dampening device (120) may prevent movement of the flat panel while any user (i.e., the associate or customer) is interfacing with the display of the computing device coupled to the flat panel (105). This resistance may allow for a user to push against the display without movement of the display occurring.

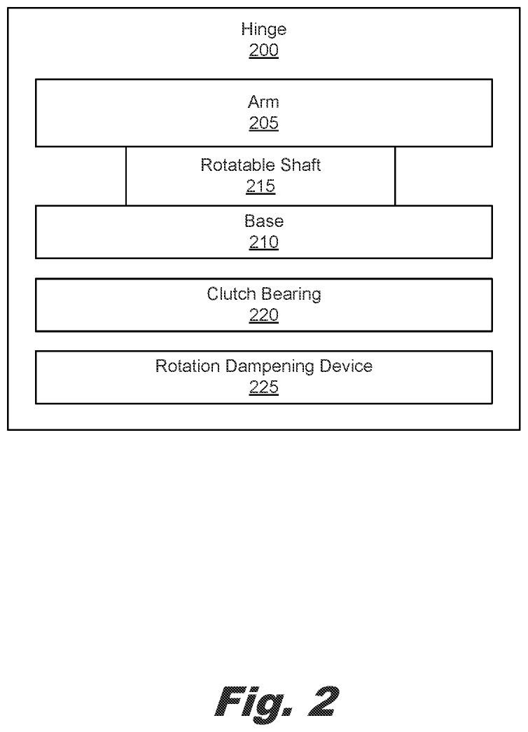

FIG. 2 is a block diagram of a hinge (200) for a display device according to an example of the principles described herein. The hinge (200) may include an arm (205) and a base (210) mechanically coupled together via a rotatable shaft (215). In a specific example, the arm (205) may be coupled to a stand or other surface onto which a computing device may be secured. In this example, the arm (205) may include a number of screw holes to pass screws therethrough and into the stand. The stand, itself, may also include a security device that secures the computing device therein unless a passcode or key is provided to remove the computing device from the stand.

The arm (205) may also include a clutch bearing (220) mechanically coupled thereto. The mechanical coupling of the clutch bearing (220) to the arm (205) may be accomplished, in an example, via an interference fit of the clutch bearing (220) into a recess formed in the arm (205). In another example, an outer surface of the clutch bearing (220) may include a keyway or spline that interfaces with an internal surface of a recess formed in the arm (205) so as to mechanically couple the clutch bearing (220) to the arm (205).

The clutch bearing (220) may also be mechanically coupled to the rotatable shaft (215) so that the clutch bearing (220) allows for free movement of the arm (205) and clutch bearing (220) about the rotatable shaft (215) in a first direction. However, the clutch bearing (220) prevents the arm (205) from being rotated about the rotatable shaft (215) in a second direction. The coupling of the clutch bearing (220) to the rotatable shaft (215), in an example, may be accomplished via the use of a keyway and spline with one or the other formed on either one of the rotatable shaft (215) or an internal surface of the clutch bearing (220). The use of the keyway and spline interface between the clutch bearing (220) and rotatable shaft (215) allows for the coupling of the clutch bearing (220) to the rotatable shaft (215) in a rotational direction but also allows for disassembly of the arm (205)/clutch bearing (220) from the rotatable shaft (215) when moved laterally relative to each other. However, the internal mechanics of the clutch bearing (220) allows for rotation of the arm (205) about the rotatable shaft (215) in a first rotational direction but prevents such rotation in a second rotational direction. This may be done due to a ratcheting feature within the internal workings of the clutch bearing (220). In an example, the clutch bearing (220) may be a sprag clutch bearing.

The hinge (200) may further include a rotation dampening device (225). The rotation dampening device (225) may increase the resistance to rotate the arm with the shaft in the second direction. Because the clutch bearing (220) prevents the rotation of the arm (205) about the rotatable shaft (215), the rotation dampening device (225) dampens the movement of the arm (205)/rotatable shaft (215) in the second direction. The rotation dampening device (225) may be mechanically coupled to the rotatable shaft (215) at an end of the rotatable shaft (215). The rotation dampening device (225), itself, may be mechanically coupled to a housing surrounding the hinge (200). Because the rotation dampening device (225) is coupled to the housing surrounding the hinge (200), it may operate independently of the arm (205) and clutch bearing (220) so as to allow for the rotatable shaft (215) to be rotatable regardless of the interface between the clutch bearing (220) and rotatable shaft (215).

In an example, the base (210) maybe fixed to a countertop or other surface. In an example, the surface may be at a POS location used to facilitate the transfer of goods and services for monetary compensation. In this example, the associate may be situated on a first side of the counter while any potential customer is situated on a second side of the counter with each facing each other. The hinge (200) may allow for the computing device on the stand coupled to the arm (205) to be passed to and from the associate for any potential transaction to be completed. In this example, the associate may interface with the computing device in order to create, for example, a bill of sale. When the bill of sale is finished, certain payments and monetary promises may be executed by a customer. So that the customer does not come around the counter to execute the bill of sale, the associate may pass the computing device to the customer by rotating the arm (205) and clutch bearing (220) about the rotatable shaft (215). By doing so the computing device is turned upside down with the display of the computing device facing the customer. In this example, the computing device may include some accelerometer or other positional device to determine the orientation of the physical hardware of the computing device. Upon recognition that the computing device is now upside down, the computing device may rotate any text and/or images presented by the display to be readable by the customer. When the customer is finished with the transaction, the associate or customer may cause the arm (205) and rotatable shaft (215) to be rotated back to the associate via use of the rotation dampening device (225) as described herein.

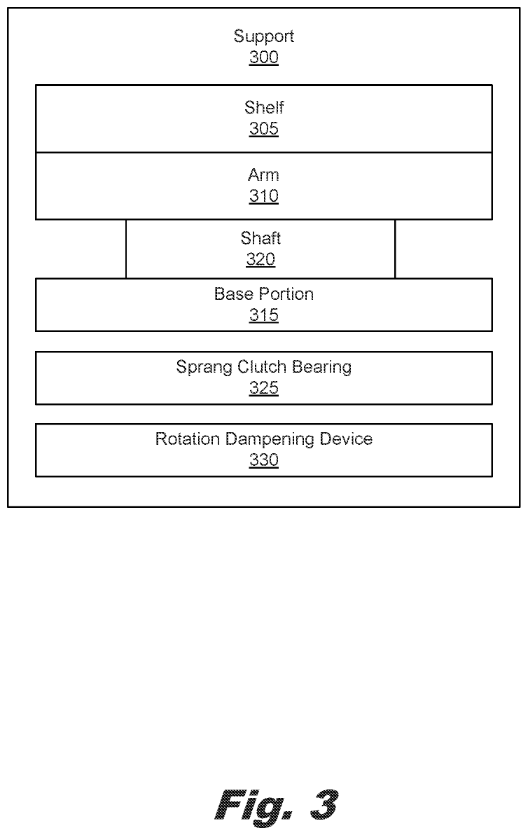

FIG. 3 is a block diagram of a support (300) for a computing device according to an example of the principles described herein. The support (300) may include a shelf (305). Because the shelf (305) is to maintain the computing device thereon, the shelf (305) may include any type of fastening device to secure the computing device thereon. This fastening device may prevent the computing device from sliding off of the shelf (305) when the shelf (305) is oriented in a position other then horizontal. As described herein, the fastening device may also include a security device to both secure the computing device to the shelf (305) as well as selectively prevent the removal of the computing device from the shelf (305) unless a combination or key is provided.

The support (300) may also include an arm (310) mechanically coupled to the shelf (305), a base portion (315) mechanically coupled to a counter, and a shaft (320) that couples the arm (310) to the base portion (315). In a specific example, the base portion (315) is mechanically coupled to the arm (310) via the shaft (320) which fits into an arm hole formed in the arm (310) and a base hole formed in the base portion (315).

As described herein, the shaft (320) may be coupled to the arm (310) using a sprag clutch bearing (325). The sprag clutch bearing (325) allows for free movement of the arm (310) about the shaft (320) in a first direction while preventing movement of the arm (310) about the shaft (320) in a second direction. Additionally, the support (300) may include a rotation dampening device (330) coupled to a housing of the support (300) and the shaft (320). As described herein the sprag clutch bearing (325) increases the resistance to move the arm with the shaft in the second direction.

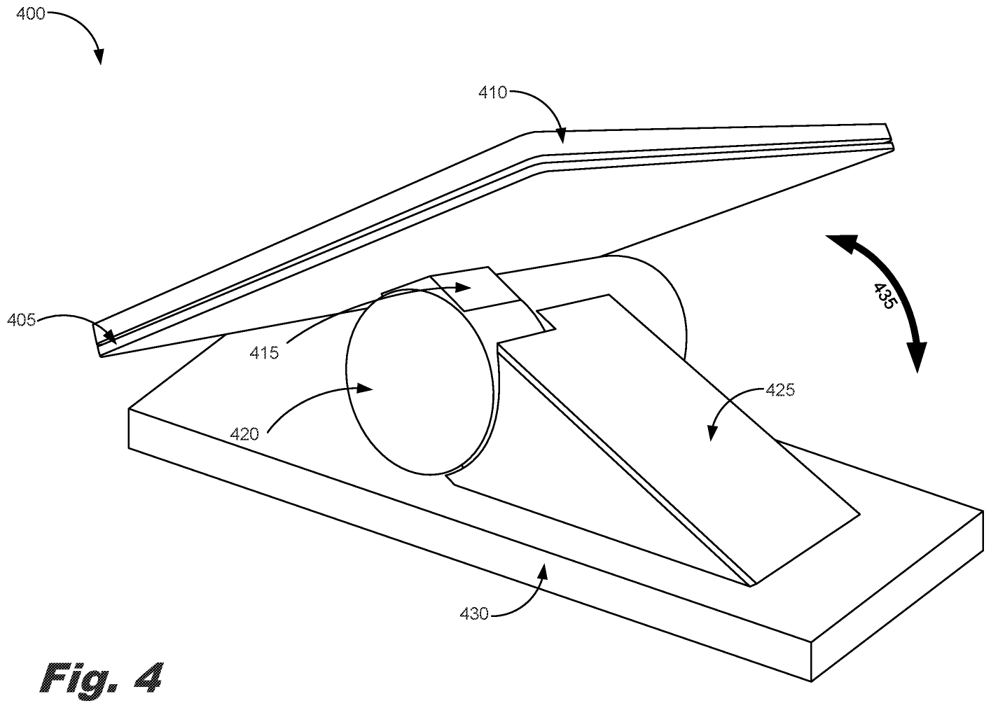

FIG. 4 is a perspective view of a support (400) for a computing device according to an example of the principles described herein. The support (400) includes a shelf (405) that serves as a location to secure a computing device (410) thereon. As described herein, the support (400) may be coupled to an arm (415). The arm (415) may form part of a hinge (420) along with a base portion (425). The base portion (425) may be secured to a countertop (430) or any other surface. In an example, the support (400), via use of the hinge (420), may allow for the computing device (410) to be moved according to the arrow (435).

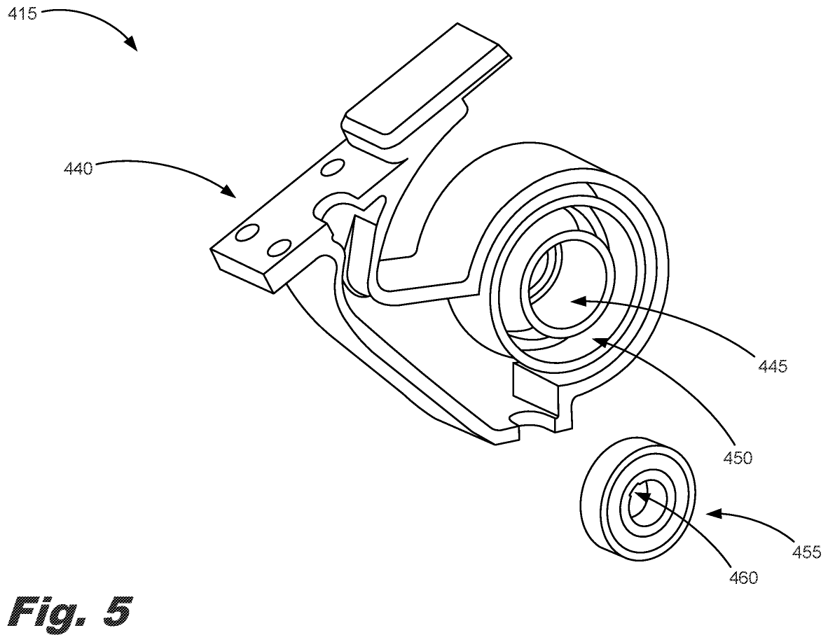

FIG. 5 is a perspective view of the arm (415) of the hinge (420) according to an example of the principles described herein. The arm (415) may include a shelf interface (440) that allows for a shelf (405) to be coupled to the arm (415). The arm (415) may also include a shaft hole (445) through which a shaft may be passed through as described herein. The arm (415) may further include a bearing recess (450) to fit a clutch bearing (455) therein to interface with the shaft.

The clutch bearing (455) itself may include a keyway (460). The keyway (460) may laterally receive a spline formed on the shaft so as to mechanically couple the clutch bearing (455) to the shaft.

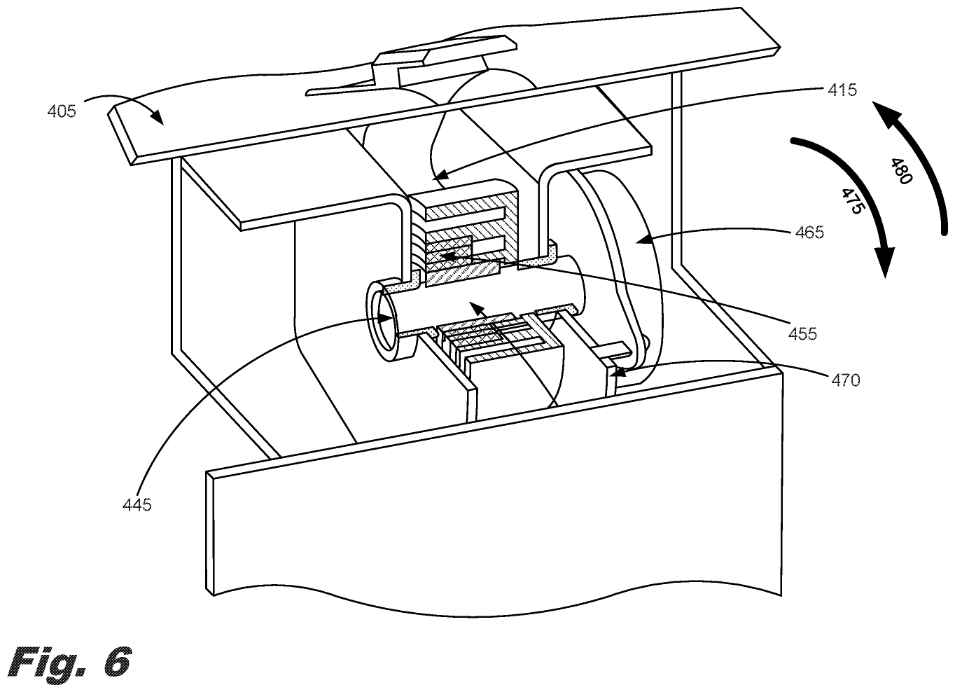

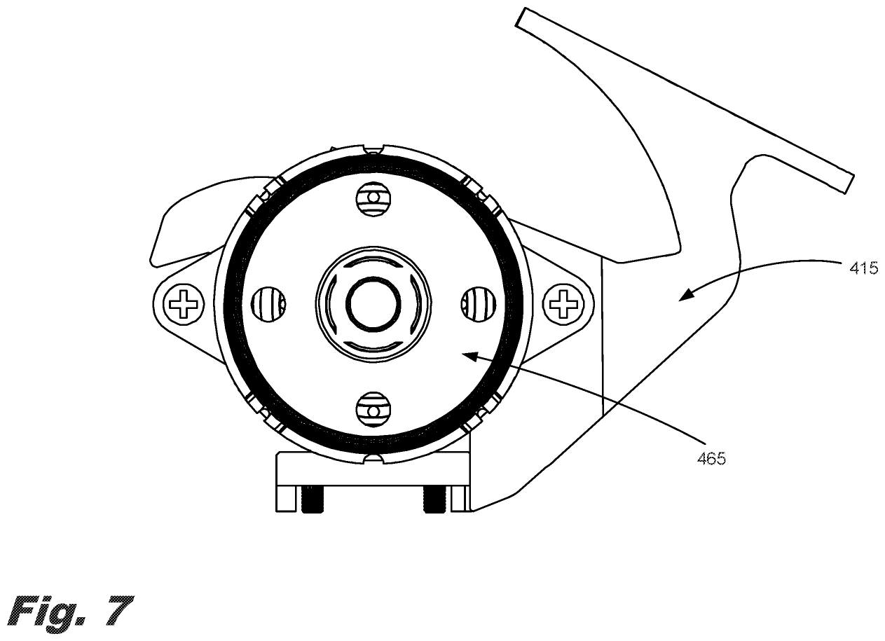

FIG. 6 is a perspective interior view of the hinge (420) shown in FIG. 4 and FIG. 7 is a side view of the hinge according to an example of the principles described herein. The hinge (420), as described herein, includes an arm (415) coupled to a base (not shown) via a shaft (460). The shaft (460) may be coupled to a dampening device (465) as described herein. The dampening device (465) itself may be coupled to a housing (470) of the system described herein to be independent of the arm (415) and base.

As described herein, the hinge (420) may allow for the shelf (405) to move in a first direction as indicated by a first arrow (475). The clutch bearing (455) may allow for movement of the shelf (405)/arm (415) in the rotational direction about the shaft (460) in the first direction but prevents movement of the shelf (405)/arm (415) about the shaft (460) in a second direction as indicated by a second arrow (480). When the shelf (405) is to be moved in a rotational direction as indicated by the second arrow (480), the clutch bearing (455) may prevent the rotational movement of the clutch bearing (455)/arm (415) about the shaft (460). However, the dampening device (465) may be coupled to the shaft (460) such that the ratcheting effect of the clutch bearing (455) causes all of the shaft (460), clutch bearing (455), and arm (415) to be moved as a single piece, albeit in a dampened manner. The dampening device (465) may be coupled to the housing (470) of the hinge (420) so as to be operated independent of the arm (415), clutch bearing (455), and shelf (405). In an example, the interfaces between the base portion and the arm (415) may include any number of detents so as to provide a holding force when the arm (415) has been moved in the first direction (475) described herein. In another example, a spring may be used to apply a holding force or biased when the arm (415) has been moved in the first direction (475).

The specification and figures describe a hinge that allows for the selective positioning of a computing device between a customer and an associate as, for example, a POS transaction. Such an arrangement allows for better interaction between an associate and a customer by allowing for a relatively quicker access to a computing device by both parties. The arrangement provides for an infinite number of tilt orientations of the computing device. Because of the use of the clutch bearing and dampening device, the hinge may be easily presented to a customer and retrieved in a manner that provides for a smooth transition between the associate and the customer. The robustness of the hinge may be resilient enough to be used for tens of thousands of transactions (i.e., passes between an associate and a customer).

The preceding description has been presented to illustrate and describe examples of the principles described. This description is not intended to be exhaustive or to limit these principles to any precise form disclosed. Many modifications and variations are possible in light of the above teaching.

What is claimed is:

1. A hinge system, comprising:
a flat panel to hold a computing device thereon;
a hinge coupled to the flat panel to flip the flat panel over to selectively present the computing device to one of a first and second facing users, the hinge comprising:
a clutch bearing that allows for rotation relative to a shaft in a first direction to a first of the facing users but prevents rotation of the clutch bearing relative to a shaft in a second direction;
a dampening device to allow for selective rotation of the shaft in the second direction.

2. The hinge system of claim 1, wherein the hinge comprises a spring to prevent free fall of the flat panel in any of the first direction and second direction.

3. The hinge system of claim 1, wherein the maximum rotation from the first to the second direction of the flat panel is 60 degrees.

4. The hinge system of claim 3, wherein the dampening device provides for an infinite number of tilt angles within the 60 degrees.

5. The hinge system of claim 1, wherein the dampening device prevents movement of the flat panel when a user is interfacing with a display device of the computing device.

6. The hinge system of claim 1, comprising arm coupled to a base via the shaft.

7. The hinge system of claim 1, wherein the clutch bearing is a sprag clutch bearing and wherein an interior wall of the sprag clutch bearing comprises a keyway to interface with a spline formed on the shaft.

8. A hinge for a display device, comprising:
an arm;
a base mechanically coupled to the arm via a rotatable shaft;
a clutch bearing to allow for free movement of the arm in a first direction about the rotatable shaft while preventing rotation of the arm about the rotatable shaft in a second direction; and
a rotation dampening device to increase the resistance to rotate the arm with the rotatable shaft in the second direction.

9. The hinge of claim 8, comprising a detent at an interface between the arm and base to provide a holding force when the arm has been moved in the first direction.

10. The hinge of claim 8, comprising a locking mechanism to lock the arm relative to the base when the arm has been moved in the first direction.

11. The hinge of claim 8, wherein the clutch bearing is a sprag clutch bearing.

12. The hinge of claim 11, wherein an interior wall of the sprag clutch bearing comprises a keyway to interface with a spline formed on the shaft.

13. A support for a computing device, comprising:
a shelf to hold and maintain a computing device thereon;
an arm mechanically coupled to the shelf;
a base portion mechanically coupled to the arm via a shaft fit into an arm hole formed in the arm and a base hole formed in the base portion;
a sprag clutch bearing to allow for free movement of the arm about the shaft in a first direction while preventing movement of the arm about the shaft in a second direction; and
a rotation dampening device to increase the resistance to move the arm with the shaft in the second direction.

14. The support for a computing device of claim 13, wherein the shelf comprises a locking mechanism to lock the computing device to the shelf.

15. The support for a computing device of claim 13, wherein an interior wall of the sprag clutch bearing comprises a keyway to interface with a spline formed on the shaft.
